(19) United States
(12) Patent Application Publication
(10) Pub. No.: US 2007/0046189 A1
(43) Pub. Date: Mar. 1, 2007

(54) Intermediate connector for a tandem OLED device

(75) Inventors: Tukaram K. Hatwar, Penfield, NY (US); William J. Bagley, Webster, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/217,026

(22) Filed: Aug. 31, 2005

(51) Int. Cl. H01L 51/52; H01L 51/54

(52) U.S. Cl. 313/506; 313/504; 428/690; 428/917; 257/40; 257/102; 257/103; 257/E51.049; 257/E51.043; 257/E51.05

(57) ABSTRACT

A tandem OLED device includes an anode, a cathode, at least first and second electroluminescent units disposed between the anode and the cathode. The electroluminescent units include an individually selected organic light-emitting layer and an intermediate connector disposed between the first and second electroluminescent units. The intermediate connector includes an n-type doped organic layer having an n-type dopant and an electron-transporting material. The electron-transporting material is a mixture of a first organic compound that has the lowest LUMO value of the compounds in the n-type doped organic layer, in an amount greater than or equal to 10% by volume and less than 100% by volume of the layer; at least one second organic compound exhibiting a higher LUMO value than the first organic compound.

### CROSS REFERENCE TO RELATED APPLICATIONS

Reference is made to commonly assigned U.S. patent application Ser. No. 11/077,218, filed Mar. 10, 2005 by Begley et al., entitled “Organic Light-Emitting Devices With Mixed Electron Transport Materials”; U.S. patent application Ser. No. 11/110,071, filed Apr. 20, 2005 by Hatwar et al., entitled “Tandem OLED Device”; and U.S. patent application Ser. No. ______, filed concurrently herewith, by Hatwar et al., entitled “Electron-Transporting Layer for White OLED Device” the disclosures of which are incorporated herein by reference.

### FIELD OF THE INVENTION

The present invention relates to tandem OLED devices, and more particularly, to an intermediate connector for use in such devices.

### BACKGROUND OF THE INVENTION

Organic electroluminescent (EL) devices or organic light-emitting diodes (OLEDs) are electronic devices that emit light in response to an applied potential. The structure of an OLED includes, in sequence, an anode, an organic electroluminescent unit, and a cathode. The organic electroluminescent unit disposed between the anode and the cathode is commonly comprised of an organic hole-transporting layer (HTL) and an organic electron-transporting layer (ETL). Holes and electrons recombine and emit light in the ETL near the interface of HTL/ETL. Tang et al., “Organic Electroluminescent Diodes”, Applied Physics Letters, 51, 913 (1987), and commonly assigned U.S. Pat. No. 4,769,292 demonstrated highly efficient OLEDs using such a layer structure. Since then, numerous OLEDs with alternative layer structures have been disclosed. For example, there are three layer OLEDs that contain an organic light-emitting layer (LEL) between the HTL and the ETL, such as that disclosed by Adachi et al., “Electroluminescence in Organic Films with Three-Layer Structure”, Japanese Journal of Applied Physics, 27, L269 (1988), and by Tang et al., “Electroluminescence of Doped Organic Thin Films”, Journal of Applied Physics, 65, 3610 (1989). The LEL commonly includes a host material doped with a guest material wherein the layer structures are denoted as HTL/LEL/ETL. Further, there are other multilayer OLEDs that contain more functional layers in the devices. At the same time, many kinds of EL materials are also synthesized and used in OLEDs. These new structures and new materials have further resulted in improved device performance.

An OLED is actually a current-driven device. Its luminance is proportional to current density, but its lifetime is inversely proportional to current density. In order to achieve high brightness, an OLED has to be operated at a relatively high current density, but this will result in a short lifetime. Thus, it is critical to improve the luminous efficiency of an OLED while operating at the lowest possible current density consistent with the intended luminance requirement to increase the operational lifetime.

In order to dramatically improve luminous efficiency and to increase lifetime in OLED, a tandem OLED (or stacked OLED, or cascaded OLED) structure, in which several individual OLEDs are stacked vertically and driven by only a single power source, has been fabricated (see U.S. Pat. Nos. 6,337,492, 6,107,734, 6,717,358, US Patent Publication Nos. 2003/0170491 A1, 2003/0189401 A1, and JP Patent Publication No. 2003/045676A). In a tandem OLED having a number of N (where N>1) electroluminescent units, the luminous efficiency can be N times as high as that of a conventional OLED containing only one electroluminescent unit (of course, the drive voltage can also be N times as high as that of the conventional OLED). Therefore, in one aspect to achieve long lifetime, the tandem OLED needs only about 1/N of the current density used in the conventional OLED to obtain the same luminance while the lifetime of the tandem OLED will be about N times that of the conventional OLED. In the other aspect to achieve high luminance, the tandem OLED needs only the same current density used in the conventional OLED to obtain a luminance N times as high as that of the conventional OLED while maintaining about the same lifetime.

Although tandem OLEDs have many advantages, one disadvantage is the increased drive voltage. In many electronic systems, e.g., in some active matrix designs, the available voltage is limited. Thus, there is a need to reduce the voltage necessary to drive tandem OLEDs. One way to lower driving voltage in a tandem OLED is to provide a connecting layer between electroluminescent units, wherein the connector layer includes an n-type doped organic layer, which typically includes an electron-transporting material doped with a low-work function metal. However, the doped metal can cause excited-state quenching and lower the luminance efficiency. This occurs if the n-type doped organic layer is directly on the light-emitting layer, or if the electron-transporting material selected for the n-type doped organic layer does not effectively bind the metal dopant, thus permitting diffusion of the metal into the light-emitting layer. Such a situation also shortens the lifetime of the OLED device.

In addition to continued need to provide OLEDs having improved lifetime and efficiency, it is desirable to improve manufacturability of OLED devices. One way to simplify manufacturing is to reduce shadow mask patterning and instead provide a white light-emitting OLED with color filters. For lowest power consumption, it is often advantageous for the chromaticity of the white light-emitting OLED to be close to CIE D₆₅, i.e., CIE x=0.31 and CIE y=0.33. This is particularly the case for so-called RGBW displays having red, green, blue, and white pixels. When using tandem architecture to make a white light-emitting OLED, therefore, it can be important that the chromaticity remain near CIE D₆₅. That is, structural modifications of the tandem structure to reduce voltage should still permit a chromaticity near CIE D₆₅. Similarly, for predictable manufacturing, it is useful if the color of a single electroluminescent unit white-emitting OLED is nearly the same in a tandem configuration.

For these reasons, there are continuing needs for organic EL device components that will provide even lower device drive voltages and hence lower power consumption, while maintaining high luminance efficiencies and long lifetimes combined with high color purity, and which can be used in tandem OLED devices.

### SUMMARY OF THE INVENTION

It is an object of the present invention to make a tandem OLED device having a low drive voltage, high efficiency, and long lifetime.

It is a further object of the present invention to make a tandem broadband or white light-emitting OLED device having a low drive voltage, high efficiency, long lifetime, and appropriate chromaticity.

These objects are achieved by a tandem OLED device, comprising:

a) an anode;

b) a cathode;

c) at least first and second electroluminescent units disposed between the anode and the cathode, wherein each of the electroluminescent units includes at least one individually selected organic light-emitting layer; and

d) an intermediate connector disposed between the first and second electroluminescent units, wherein the intermediate connector includes an n-type doped organic layer having an n-type dopant and an electron-transporting material, wherein such electron-transporting material is a mixture of:
i) a first organic compound that has the lowest LUMO value of the compounds in the n-type doped organic layer, in an amount greater than or equal to 10% by volume and less than 100% by volume of the layer; and
ii) at least one second organic compound exhibiting a higher LUMO value than the first organic compound, where at least one of the second organic compounds is a low voltage electron-transporting material, and the total amount of such second organic compounds(s) is less than or equal to 90% by volume of the layer.

### Advantages

It is an advantage of this invention that it provides an OLED device that has better stability and operates at a lower voltage. It is a further advantage of this invention that can provide a lower operating voltage for the OLED device without a color shift that is sometimes seen with materials that provide a lower operating voltage.

### BRIEF DESCRIPTION OF THE DRAWINGS

FIG. 1 depicts a schematic cross sectional view of a tandem OLED, having N(N>1) electroluminescent units connected in series by N−1 intermediate connectors;

FIG. 2 depicts a schematic cross sectional view of a specific tandem OLED, having two electroluminescent units connected in series by an intermediate connector; and

FIGS. 3A-3G depict a schematic cross sectional views of specific intermediate connector configurations.

### DETAILED DESCRIPTION OF THE INVENTION

Several terms to be used in the following description are explained herein. The term “full color” is employed to describe the emission color in the red, green, and blue regions of the visible spectrum. The red, green, and blue colors constitute the three primary colors from which other colors can be produced by appropriate mixing. Broadband emission is light that has significant components in multiple portions of the visible spectrum, for example, blue and green. Broadband emission can also include the situation where light is emitted in the red, green, and blue portions of the spectrum in order to produce white light. White light is that light that is perceived by a user as having a white color, or light that has an emission spectrum sufficient to be used in combination with color filters to produce practical full color displays. Although the white light can have a strong hue and still be useful, white color preferably has Commission Internationale de l'Eclairage (CIE) coordinates of about CIE x=0.31±0.05 and CIE y=0.33±0.05. This is the color of a D₆₅ white, which is particularly advantageous for RGBW displays having red, green, blue, and white pixels as described in WO 2004/061963. The term “pixel” is employed in its art recognized usage to designate an area of a display panel that can be stimulated to emit light independently. The term “n-type doped organic layer” means an organic layer that has semiconducting properties after doping, and the electrical current through this layer is substantially carried by the electrons. The term “p-type doped organic layer” means an organic layer that has semiconducting properties after doping, and the electrical current through this layer is substantially carried by the holes. A “high work function metal” is defined as a metal having a work function no less than 4.0 eV. Likewise, a “low work function metal” is defined as a metal having a work function less than 4.0 eV.

The construction of a tandem white OLED device using multiple electroluminescent units having has been described in commonly assigned U.S. patent application Ser. No. 10/922,606 filed Aug. 20, 2004 by Liang-Sheng Liao et al., entitled “White OLED Having Multiple White Electroluminescence Units”, the disclosure of which is herein incorporated by reference. In this case, it was difficult for a tandem white OLED device to maintain the initial white color.

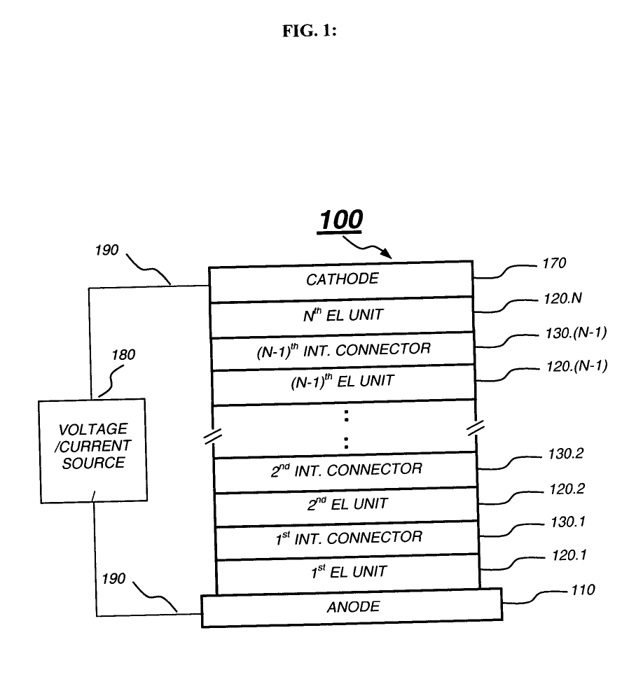

FIG. 1 shows a tandem OLED device 100 in accordance with the present invention. This tandem OLED device has an anode 110 and a cathode 170, at least one of which is transparent. Disposed between the anode and the cathode are N electroluminescent units (indicated by “EL unit”) and N−1 intermediate connectors (indicated by “int. connector”), where N is an integer greater than 1. That is, this invention requires at least first and second electroluminescent units disposed between the anode and cathode, and an intermediate connector disposed between the first and second electroluminescent units. The electroluminescent units, stacked and connected serially, are designated 120.1 to 120.N, where 120.1 is the first electroluminescent unit (adjacent to the anode), 120.2 is the second electroluminescent unit, 120.N−1 is the (N−1)^{th} electroluminescent unit, and 120.N is the Nth electroluminescent unit (near the cathode). The intermediate connectors, disposed between the electroluminescent unit, are designated 130.1 to 130.(N−1), where 130.1 is the first intermediate connector disposed between electroluminescent units 120.1 and 120.2; 130.2 is the second intermediate connector in contact with electroluminescent unit 120.2 and another electroluminescent unit (not shown in the figure); and 130.(N−1) is the last intermediate connector disposed between electroluminescent units 120.(N−1) and 120.N. The anode 110 and cathode 170 of tandem OLED device 100 are externally connected to voltage/current source 180 through electrical conductors 190. Tandem OLED device 100 is operated by applying an electric potential produced by a voltage/current source 180.

Each electroluminescent unit in tandem OLED device 100 is capable of supporting hole injection, hole transport, electron injection, electron transport, and electron-hole recombination to produce light, and thus can comprise a plurality of layers. Such layers can include a hole-injecting layer (HIL), a hole-transporting layer (HTL), at least one individually selected organic light-emitting layer (LEL), an electron-transporting layer (ETL), an electron-injecting layer (EIL), hole-blocking layer (HBL), electron-blocking layer (EBL), an exciton-blocking layer (XBL), and others known in the art. Various layers can serve multiple functions (e.g., an ETL can also serve as an HBL), and there can be multiple layers that have a similar function (e.g., there can be several LELs, ETLs). There are many organic electroluminescent multilayer structures known in the art that can be used as electroluminescent units of the present invention. Some nonlimiting examples include, HTL/LEL(s)/ETL, HTL/LEL(s)/EIL, HIL/HTL/LEL(s)/ETL, HIL/HTL/LEL(s)/ETL/EIL, HIL/HTL/EBL or XBL/LEL(s)/ETL/EIL, HIL/HTL/LEL(s)/HBL/ETL/EIL. Each electroluminescent unit in tandem OLED device 100 can have the same or different layer structures relative to other electroluminescent units. Preferably, the layer structure of the electroluminescent units is of HTL/LEL(s)/ETL, wherein the electroluminescent unit adjacent to anode 110 (e.g. 120.1) has a HIL between the anode and the HTL, and wherein the electroluminescent unit adjacent to cathode 170 (e.g. 120.N) has an EIL disposed between the cathode and the ETL. The number of LELs in each of the electroluminescent units can vary typically from 1 to 3. Moreover, each of the electroluminescent units in the tandem OLED can emit the same or different color.

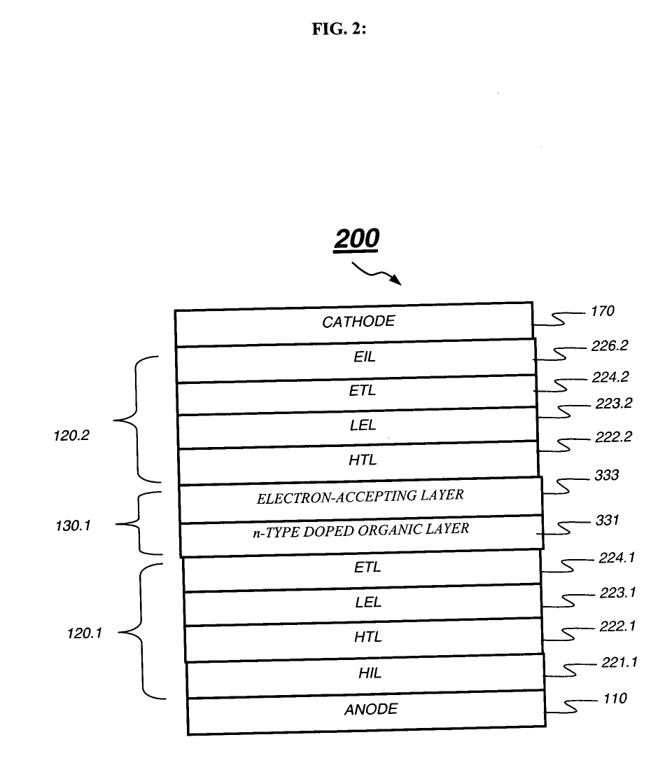

The present invention is more clearly set forth in the embodiment shown in FIG. 2. Tandem OLED device 200 has a first electroluminescent unit 120.1 and a second electroluminescent unit 120.2 connected in series by intermediate connector 130.1. Those skilled in the art will recognize that electroluminescent units 120.1 and 120.2 represent only two of the many OLED structures that can be used in this invention. First electroluminescent unit 120.1 in this arrangement includes HIL 221.1 (adjacent to anode 110), HTL 222.1, LEL 223.1, and ETL 224.1. Intermediate connector 130.1 includes n-type doped organic layer 331, and can include other layers such as electron-accepting layer 333. Some further embodiments of intermediate connector 130.1 will be described below. A second electroluminescent unit 120.2 includes HTL 222.2, LEL 223.2, ETL 224.2, and EIL 226.2. Cathode 170 is provided over EIL 226.2. For clarity, the power supply and electrical conductors are not shown.

The HTL includes at least one hole-transporting material such as an aromatic tertiary amine, where the aromatic tertiary amine is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals or at least one active hydrogen-containing group are disclosed by Brantley et al. in U.S. Pat. Nos. 3,567,450 and 3,658,520.

A more preferred class of aromatic tertiary amines are those which include at least two aromatic tertiary amine moieties as described by VanSlyke et al. in U.S. Pat. Nos. 4,720,432 and 5,061,569. The HTL can be formed of a single or a mixture of aromatic tertiary amine compounds. Illustrative of useful aromatic tertiary amines are the following:
1,1-Bis(4-di-p-tolylaminophenyl)cyclohexane;
1,1-Bis(4-di-p-tolylaminophenyl)-4-phenylcyclohexane;
N,N,N′,N′-tetraphenyl-4,4′″-diamino-1,1′:4′, 1″:4″, 1′″-quaterphenyl;
Bis(4-dimethylamino-2-methylphenyl)phenylmethane;
1,4-bis[2-[4-[N,N-di(p-tolyl)amino]phenyl]vinyl]benzene (BDTAPVB);
N,N,N′,N′-Tetra-p-tolyl-4,4′-diaminobiphenyl;
N,N,N′,N′-Tetraphenyl-4,4′-diaminobiphenyl;
N,N,N′,N′-tetra-1-naphthyl-4,4′-diaminobiphenyl;
N,N,N′,N′-tetra-2-naphthyl-4,4′-diaminobiphenyl;
N-Phenylcarbazole;
4,4′-Bis[N-(1-naphthyl)-N-phenylamino]biphenyl (NPB);
4,4′-Bis[N-(1-naphthyl)-N-(2-naphthyl)amino]biphenyl (TNB);
4,4′-Bis[N-(1-naphthyl)-N-phenylamino]p-terphenyl;
4,4′-Bis[N-(2-naphthyl)-N-phenylamino]biphenyl;
4,4′-Bis[N-(3-acenaphthenyl)-N-phenylamino]biphenyl;
1,5-Bis[N-(1-naphthyl)-N-phenylamino]naphthalene;
4,4′-Bis[N-(9-anthryl)-N-phenylamino]biphenyl;
4,4′-Bis[N-(1-anthryl)-N-phenylamino]-p-terphenyl;
4,4′-Bis[N-(2-phenanthryl)-N-phenylamino]biphenyl;
4,4′-Bis[N-(8-fluoranthenyl)-N-phenylamino]biphenyl;
4,4′-Bis[N-(2-pyrenyl)-N-phenylamino]biphenyl;
4,4′-Bis[N-(2-naphthacenyl)-N-phenylamino]biphenyl;
4,4′-Bis[N-(2-perylenyl)-N-phenylamino]biphenyl;
4,4′-Bis[N-(1-coronenyl)-N-phenylamino]biphenyl;
2,6-Bis(di-p-tolylamino)naphthalene;
2,6-Bis[di-(1-naphthyl)amino]naphthalene;
2,6-Bis[N-(1-naphthyl)-N-(2-naphthyl)amino]naphthalene;
N,N,N′,N′-Tetra(2-naphthyl)-4,4″-diamino-p-terphenyl;
4,4′-Bis {N-phenyl-N-[4-(1-naphthyl)-phenyl]amino}biphenyl;
2,6-Bis[N,N-di(2-naphthyl)amino]fluorene;
4,4′,4″-tris[(3-methylphenyl)phenylamino]triphenylamine (MTDATA); and
4,4′-Bis[N-(3-methylphenyl)-N-phenylamino]biphenyl (TPD).

Another class of useful hole-transporting materials includes polycyclic aromatic compounds as described in EP 1 009 041. Tertiary aromatic amines with more than two amino groups can be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

The LEL includes a luminescent fluorescent or phosphorescent material where electroluminescence is produced as a result of electron-hole pair recombination in this region. The light-emitting layer can be comprised of a single material, but more commonly contains a host material doped with a guest emitting material or materials where light emission comes primarily from the emitting materials and can be of any color. This guest emitting material is often referred to as a light-emitting dopant. The host materials in the light-emitting layer can be an electron-transporting material, as defined below, a hole-transporting material, as defined above, or another material or combination of materials that support hole-electron recombination. The emitting material is typically chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small nonpolymeric molecules or polymeric materials including polyfluorenes and polyvinylarylenes, e.g., poly(p-phenylenevinylene), PPV. In the case of polymers, small molecule emitting materials can be molecularly dispersed into a polymeric host, or the emitting materials can be added by copolymerizing a minor constituent into a host polymer.

An important relationship for choosing an emitting material is a comparison of the bandgap potential which is defined as the energy difference between the highest occupied molecular orbital (HOMO) and the lowest unoccupied molecular orbital (LUMO) of the molecule. For efficient energy transfer from the host to the emitting material, a necessary condition is that the band gap of the dopant is smaller than that of the host material. For phosphorescent emitters (including materials that emit from a triplet excited state, i.e., so-called “triplet emitters”) it is also important that the host triplet energy level of the host be high enough to enable energy transfer from host to emitting material.

Host and emitting materials known to be of use include, but are not limited to, those disclosed in U.S. Pat. Nos. 4,768,292; 5,141,671; 5,150,006; 5,151,629; 5,405,709; 5,484,922; 5,593,788; 5,645,948; 5,683,823; 5,755,999; 5,928,802; 5,935,720; 5,935,721; 6,020,078; 6,475,648; 6,534,199; 6,661,023; US Patent Application Publications 2002/0127427 A1; 2003/0198829 A1; 2003/0203234 A1; 2003/0224202 A1; and 2004/0001969 A1.

Metal complexes of 8-hydroxyquinoline (oxine) and similar derivatives constitute one class of useful host compounds capable of supporting electroluminescence. Illustrative of useful chelated oxinoid compounds are the following:

CO-1: Aluminum trisoxine [alias, tris(8-quinolinolato)aluminum(III)];

CO-2: Magnesium bisoxine [alias, bis(8-quinolinolato)magnesium(II)];

CO-3: Bis[benzo{f}-8-quinolinolato]zinc (II);

CO-4: Bis(2-methyl-8-quinolinolato)aluminum(III)-μ-oxo-bis(2-methyl-8-quinolinolato) aluminum(III);

CO-5: Indium trisoxine [alias, tris(8-quinolinolato)indium];

CO-6: Aluminum tris(5-methyloxine) [alias, tris(5-methyl-8-quinolinolato) aluminum(III)];

CO-7: Lithium oxine [alias, (8-quinolinolato)lithium(I)];

CO-8: Gallium oxine [alias, tris(8-quinolinolato)gallium(III)]; and

CO-9: Zirconium oxine [alias, tetra(8-quinolinolato)zirconium(IV)].

Another class of useful host materials includes derivatives of anthracene, such as those described in U.S. Pat. Nos. 5,935,721, 5,972,247, 6,465,115, 6,534,199, 6,713,192, US Patent Application Publication Nos. 2002/0048687 A1, 2003/0072966 A1, and WO 2004/018587 A1. Some examples include derivatives of 9,10-dinaphthylanthracene derivatives and 9-naphthyl-10-phenylanthracene. Other useful classes of host materials include distyrylarylene derivatives as described in U.S. Pat. No. 5,121,029, and benzazole derivatives, for example, 2,2′, 2″-(1,3,5-phenylene)tris[1-phenyl-1H-benzimidazole].

Desirable host materials are capable of forming a continuous film. The light-emitting layer can contain more than one host material in order to improve the device's film morphology, electrical properties, light emission efficiency, and lifetime. Mixtures of electron-transporting and hole-transporting materials are known as useful hosts. In addition, mixtures of the above listed host materials with hole-transporting or electron-transporting materials can make suitable hosts.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrilium compounds, fluorene derivatives, periflanthene derivatives, indenoperylene derivatives, bis(azinyl)amine boron compounds, bis(azinyl)methane boron compounds, derivatives of distryrylbenzene and distyrylbiphenyl, and carbostyryl compounds. Among derivatives of distryrylbenzene, particularly useful are those substituted with diarylamino groups, informally known as distyrylamines.

Suitable host materials for phosphorescent emitters (including materials that emit from a triplet excited state, i.e., so-called “triplet emitters”) should be selected so that the triplet exciton can be transferred efficiently from the host material to the phosphorescent material. For this transfer to occur, it is a highly desirable condition that the excited state energy of the phosphorescent material be lower than the difference in energy between the lowest triplet state and the ground state of the host. However, the band gap of the host should not be chosen so large as to cause an unacceptable increase in the drive voltage of the OLED. Suitable host materials are described in WO 00/70655 A2; WO 01/39234 A2; WO 01/93642 A1; WO 02/074015 A2; WO 02/15645 A1; and US Patent Application Publication No. 2002/0117662 A1. Suitable hosts include certain aryl amines, triazoles, indoles, and carbazole compounds. Examples of desirable hosts are 4,4′-N,N′-dicarbazole-biphenyl (CBP), 2,2′-dimethyl-4,4′-N,N′-dicarbazole-biphenyl, m-(N,N′-dicarbazole)benzene, and poly(N-vinylcarbazole), including their derivatives.

Examples of useful phosphorescent materials that can be used in light-emitting layers of this invention include, but are not limited to, those described in WO 00/57676 A1; WO 00/70655 A1; WO 01/41512 A1; WO 02/15645 A1; WO 01/93642A1; WO 01/39234 A2; WO 02/074015 A2; WO 02/071813 A1; U.S. Pat. Nos. 6,458,475; 6,573,651; 6,451,455; 6,413,656; 6,515,298; 6,451,415; 6,097,147; US Patent Application Publications 2003/0017361 A1; 2002/0197511 A1; 2003/0072964 A1; 2003/0068528 A1; 2003/0124381 A1; 2003/0059646 A1; 2003/0054198 A1; 2002/0100906 A1; 2003/0068526 A1; 2003/0068535 A1; 2003/0141809 A1; 2003/0040627 A1; 2002/0121638 A1; EP 1239 526 A2; EP 1 238 981 A2; EP 1 244 155 A2; JP 2003073387A; JP 2003073388A; JP 2003059667A; and JP 2003073665A. Useful phosphorescent dopants include, but are not limited to, transition metal complexes, such as iridium and platinum complexes.

In some cases it is useful for one or more of the LELs within an electroluminescent unit to emit broadband light, for example white light, in the case wherein the light emitted by at least one of the electroluminescent units is white. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in EP 1 187 235; EP 1 182 244; U.S. Pat. Nos. 5,683,823; 5,503,910; 5,405,709; 5,283,182; 6,627,333; 6,696,177; 6,720,092; US Patent Application Publications 2002/0186214 A1; 2002/0025419 A1; and 2004/0009367 A1. In preferred embodiments, white-emitting electroluminescent units have two or more light-emitting layers that combine to produce white light. In some of these systems, the host for one light-emitting layer is a hole-transporting material.

The ETL can contain one or more metal chelated oxinoid compounds, including chelates of oxine itself, also commonly referred to as 8-quinolinol or 8-hydroxyquinoline. Such compounds help to inject and transport electrons, exhibit high levels of performance, and are readily deposited to form thin films. Exemplary oxinoid compounds have been listed above from CO-1 to CO-9.

Other electron-transporting materials include various butadiene derivatives as disclosed in U.S. Pat. No. 4,356,429 and various heterocyclic optical brighteners as described in U.S. Pat. No. 4,539,507. Benzazoles, oxadiazoles, triazoles, pyridinethiadiazoles, triazines, phenanthroline derivatives, and some silole derivatives are also useful electron-transporting materials.

Each of the layers in the electroluminescent unit can be formed from small molecule OLED materials, or polymeric LED materials, or combinations thereof. Some electroluminescent units can be polymeric and other units can be of small molecules (or nonpolymeric), including fluorescent materials and phosphorescent materials. The corresponding layer in each of the electroluminescent units in the tandem OLED can be formed using the same or different materials from those of the other corresponding layers, and can have the same or different layer thicknesses.

For a tandem OLED to function efficiently, intermediate connector 130.1 should provide effective carrier injection into the adjacent electroluminescent units. It is also preferred that the optical transparency of the layers constituting the intermediate connector should be as high as possible to permit for radiation produced in the electroluminescent units to exit the device. There are several useful configurations for the intermediate connector, but in every case, it includes at least an n-type doped organic layer 331.

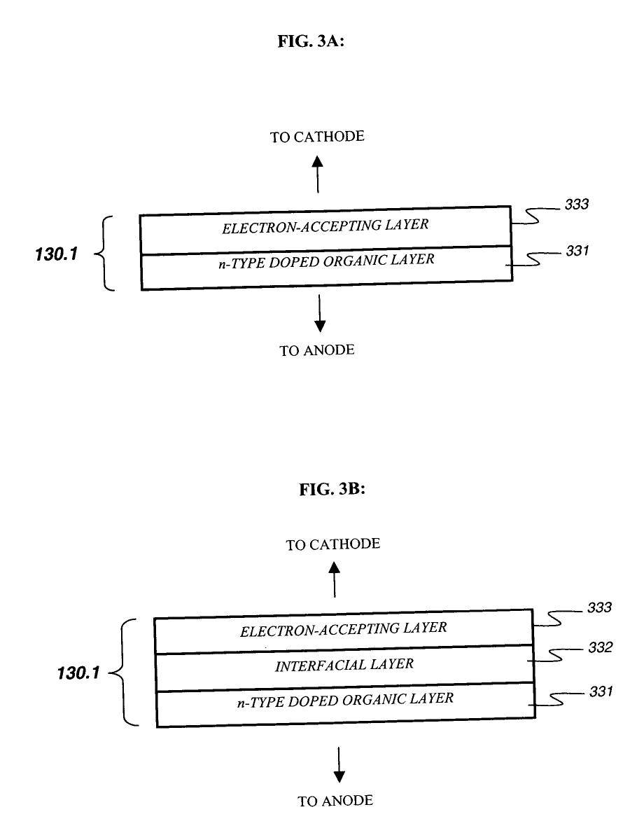

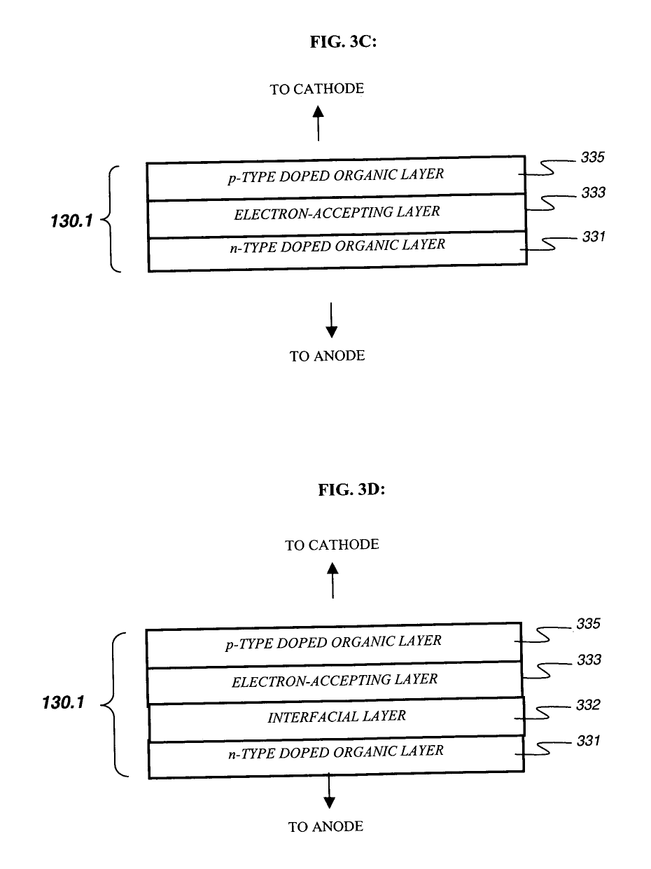

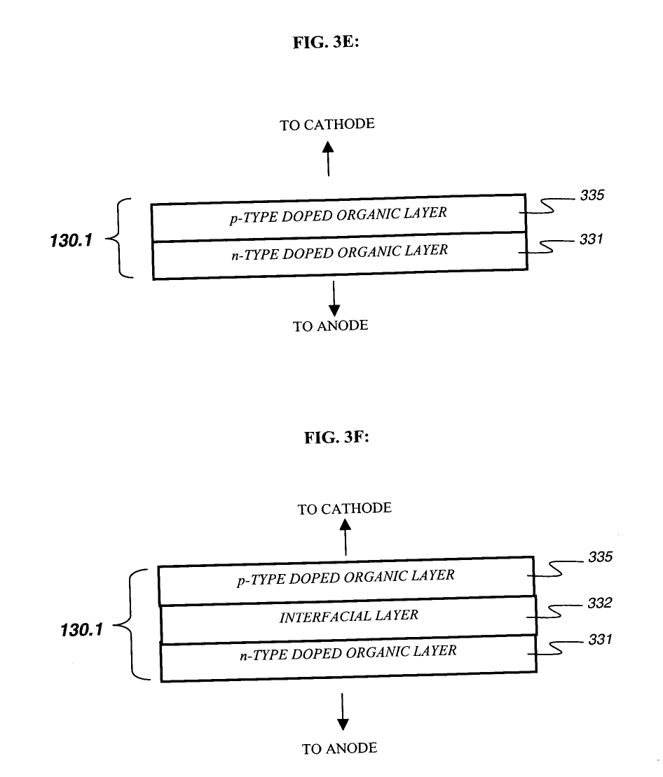

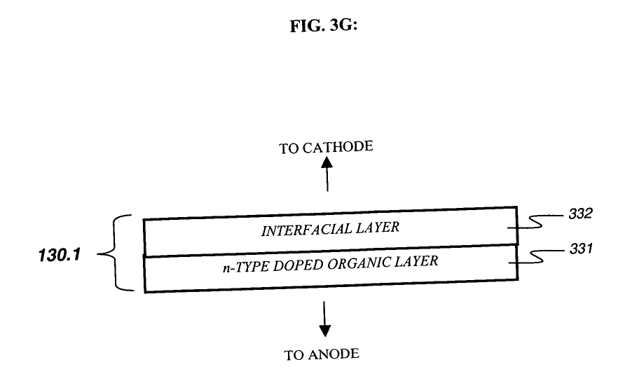

As shown in FIG. 3A, intermediate connector 130.1 of FIG. 1 and FIG. 2 can have two layers including an n-type doped organic layer 331 and an electron-accepting layer 333. Electron-accepting layer 333 is disposed closer than n-type doped organic layer 331 to cathode 170. These two layers can be in contact as shown in FIG. 3A, or intermediate connector 130.1 can include an interfacial layer 332 disposed between n-type doped organic layer 331 and electron-accepting layer 333, as shown in FIG. 3B. Intermediate connector 130.1 can also have a p-type doped organic layer 335 over electron-accepting layer 333, as shown in FIG. 3C. p-Type doped organic layer 335 is disposed closer than electron-accepting layer 333 to cathode 170. Preferably, p-type doped organic layer 335 is in contact with electron-accepting layer 333. In another embodiment, intermediate connector 130.1 can further have an interfacial layer 332 disposed between n-type doped organic layer 331 and electron-accepting layer 333, as shown in FIG. 3D. Another embodiment for intermediate connector 130.1 can include an n-type doped organic layer 331 and a p-type doped organic layer 335, wherein p-type doped organic layer 335 is disposed closer than n-type doped organic layer 331 to cathode 170, as shown in FIG. 3E. In another embodiment, intermediate connector 130.1 can further include interfacial layer 332 disposed between n-type doped organic layer 331 and p-type doped organic layer 335, as shown in FIG. 3F. Another embodiment for intermediate connector 130.1 can include an n-type doped organic layer 331 and an electron-accepting layer 333, wherein electron-accepting layer 333 is disposed closer than n-type doped organic layer 331 to cathode 170, as shown in FIG. 3G.

n-Type doped organic layer 331 of intermediate connector 130.1 has an n-type dopant and an electron-transporting material. The electron-transporting material is a mixture of: a first organic compound that has the lowest LUMO value of the compounds in n-type doped organic layer 331, and at least one second organic compound exhibiting a higher LUMO value than the first organic compound, wherein at least one of the second organic compounds is a low voltage electron-transporting material. These materials will be described further.

The n-type dopant can be a metallic material. As used herein the term “metallic material” includes both the elemental metal and compounds thereof. The metallic material is not restricted to a specific one, as long as it is a metal that can reduce at least one of the organic compounds. It can be selected from the alkali metals such as Li, alkaline earth metals such as Mg, and transition metals including rare earth metals. In particular, a metal having a work function of less than or equal to 4.2 eV can be suitably used as the metallic material, and typical examples of such metallic materials include Li, Na, K, Cs, Be, Mg, Ca, Sr, Ba, Y, La, Ce, Sm, Eu, Tb, Dy, Gd, and Yb. Preferred metallic materials are Li and Cs.

The materials used as the n-type dopants in n-type doped organic layer 331 can also include organic reducing agents with strong electron-donating properties. By “strong electron-donating properties” it is meant that the organic dopant should be able to donate at least some electronic charge to the host to form a charge-transfer complex with the host. Nonlimiting examples of organic molecules include bis(ethylenedithio)-tetrathiafulvalene (BEDT-TTF), tetrathiafulvalene (TTF), and their derivatives. In the case of polymeric hosts, the dopant can be any of the above or also a material molecularly dispersed or copolymerized with the host as a minor component. The concentration of the n-type dopant in n-type doped organic layer 331 is not restricted to a specific one, but is in the range of from 0.01% to 20% by volume of the total material in the layer. The preferred concentration of n-type dopant is in the range of 0.1% to 10% but more preferably in the range of from 1% to 8%. The thickness of n-type doped organic layer 331 is typically less than 200 nm, and preferably less than 100 nm.

The first organic compound is desirably a polycyclic aromatic compound. The polycyclic aromatic hydrocarbon compound comprises carbocyclic rings. As used herein and throughout this application, the term carbocyclic rings or groups are generally as defined by the Grant &Hackh 's Chemical Dictionary, Fifth Edition, McGraw-Hill Book Company. A carbocyclic ring is any aromatic or non-aromatic ring system wherein the ring comprises only carbon atoms. The polycyclic aromatic hydrocarbon compounds of this invention comprise at least two fused rings, at least one of which is aromatic. Carbocyclic ring systems useful for the current invention for the polycyclic aromatic hydrocarbon are selected from anthracenes, phenanthrenes, tetracenes, xanthenes, perylenes, fluoranthenes, and periflanthrenes, any of which can be further substituted.

In one embodiment, the first organic compound can be selected from naphthacene derivatives that are represented by Formula A: 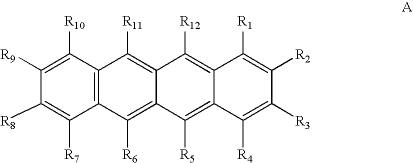
wherein:

R₁, R₂, R₃, R₄, R₅, R₆, R₇, R₈, R₉, R₁₀, R₁₁, and R₁₂ are independently selected as hydrogen or substituents;

provided that any of the indicated substituents can join to form further fused rings.

Unless otherwise specifically stated, use of the term “substituted” or “substituent” means any group or atom other than hydrogen. Additionally, when the term “group” is used, it means that when a substituent group contains a substitutable hydrogen, it is also intended to encompass not only the substituent's unsubstituted form, but also its form further substituted with any substituent group or groups as herein mentioned, so long as the substituent does not destroy properties necessary for device utility. Suitably, a substituent group can be halogen or can be bonded to the remainder of the molecule by an atom of carbon, silicon, oxygen, nitrogen, phosphorous, sulfur, selenium, or boron. The substituent can be, for example, halogen, such as chloro, bromo or fluoro; nitro; hydroxyl; cyano; carboxyl; or groups which can be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which can be substituted and which contain a 3 to 7 membered heterocyclic ring composed of carbon atoms and at least one hetero atom selected from the group consisting of oxygen, nitrogen, sulfur, phosphorous, or boron. Such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents can themselves be further substituted one or more times with the described substituent groups. The particular substituents used can be selected by those skilled in the art to attain desirable properties for a specific application and can include, for example, electron-withdrawing groups, electron-donating groups, and steric groups. When a molecule can have two or more substituents, the substituents can be joined together to form a ring such as a fused ring unless otherwise provided. Generally, the above groups and substituents thereof can include those having up to 48 carbon atoms, typically 1 to 36 carbon atoms and usually less than 24 carbon atoms, but greater numbers are possible depending on the particular substituents selected.

Preferentially, the first organic compound of the invention represented by Formula I is one in which at least one of R₁, R₂, R₃, R₄, R₅, R₆, R₇, R₈, R₉, R₁₀, R₁₁ , and R₁₂ are independently selected from alkyl and aryl groups.

In another embodiment, the first organic compound can be selected from anthracene derivatives that are represented by Formula B: 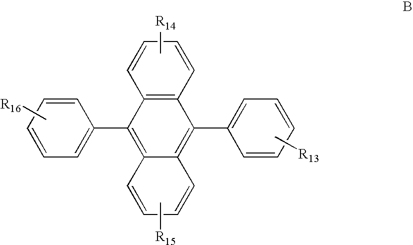
wherein:

R₁₃, R₁₄, R₁₅ and R₁₆ represent hydrogen or one or more substituents selected from the following groups:

Group 1: hydrogen, alkyl and alkoxy groups typically having from 1 to 24 carbon atoms;

Group 2: a ring group, typically having from 6 to 20 carbon atoms;

Group 3: the atoms necessary to complete a carbocyclic fused ring group such as naphthyl, anthracenyl, pyrenyl, and perylenyl groups, typically having from 6 to 30 carbon atoms;

Group 4: the atoms necessary to complete a heterocyclic fused ring group such as furyl, thienyl, pyridyl, and quinolinyl groups, typically having from 5 to 24 carbon atoms;

Group 5: an alkoxylamino, alkylamino, and arylamino group typically having from 1 to 24 carbon atoms; and

Group 6: fluorine, chlorine, bromine and cyano radicals.

More specifically, the first organic compound of the invention can be selected from compounds represented by the following structures:

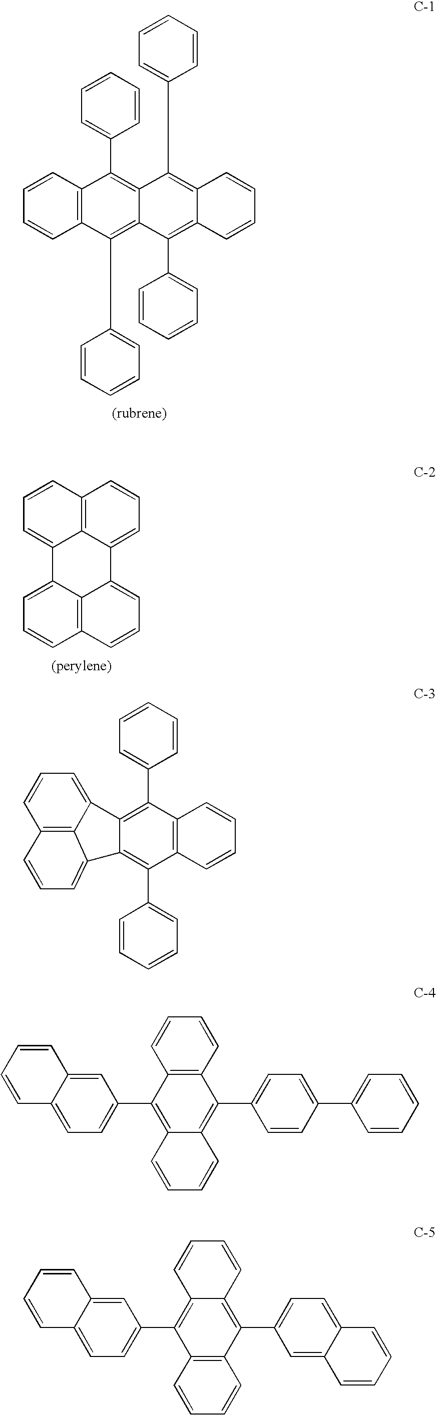

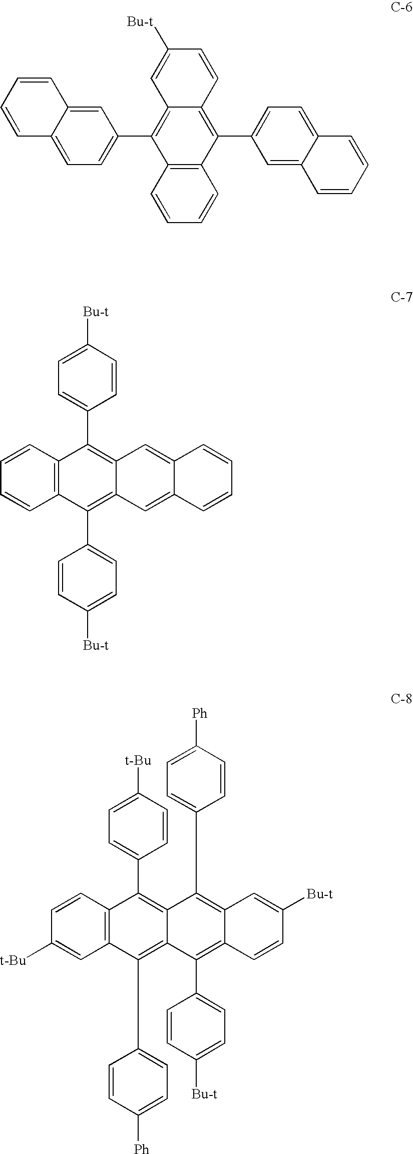

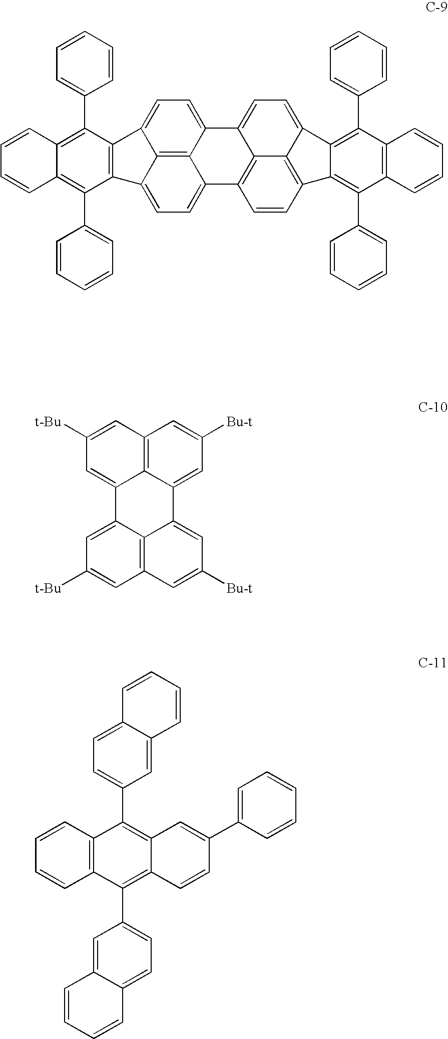

Also included in the above structures are compounds containing the depicted structural features with substituents suitable to render said structures with the desired properties to function as first organic compound materials of the invention.

It is a requirement of the first organic compound that it have the lowest LUMO value of the compounds in the n-type doped organic layer. A particularly preferred first organic compound is rubrene (Structure C-1) or a derivative thereof.

The electron-transporting material of n-type doped organic layer 331 also includes one or more second organic compounds exhibiting a higher LUMO value than the first organic compound. At least one of the second organic compounds is a low voltage electron-transporting material. As used herein, the term “low voltage electron-transporting material” means those materials that, when incorporated alone into the electron transporting layer, result in drive voltages of 13 volts or less. Low voltage electron transport materials with drive voltages of 10 volts or less are also useful as second compounds of the invention while materials of 8 volts or less are preferred as second compounds. Such materials have been described in detail by Begley et al. in U.S. patent application Ser. No. 11/077,218, filed Mar. 10, 2005 entitled “Organic Light-Emitting Devices With Mixed Electron Transport Materials”. The second organic compound can optionally comprise carbocyclic and/or heterocyclic rings. A heterocyclic ring is any aromatic or non-aromatic ring system containing both carbon and non-carbon atoms such as nitrogen (N), oxygen (O), sulfur (S), phosphorous (P), silicon (Si), gallium (Ga), boron (B), beryllium (Be), indium (In), aluminum (Al), and other elements found in the periodic table useful in forming ring systems. For the purpose of this invention, also included in the definition of a heterocyclic ring are those rings that include coordinate bonds. The definition of a coordinate bond can be found in Grant & Hackh's Chemical Dictionary, page 91. In essence, a coordinate bond is formed when electron rich atoms, such as O or N, donate a pair of electrons to electron-deficient atoms such as Al or B. One such example is found in tris(8-quinolinolato)aluminum(III), also referred to as Alq, wherein the nitrogen on the quinoline moiety donates its lone pair of electrons to the aluminum atom, thus forming the heterocycle and hence providing Alq with a total of 3 fused rings. The definition of work function can be found in CRC Handbook of Chemistry and Physics, 70th Edition, 1989-1990, CRC Press Inc., page F-132 and a list of the work functions for various metals can be found on pages E-93 and E-94. Carbocyclic and heterocyclic ring systems useful for the current invention for the second compounds are selected from metal and non-metal chelated oxinoids, anthracenes, bipyridyls, butadienes, imidazoles, phenanthrenes, phenanthrolines, styrylarylenes, benzazoles, buckministerfullerene-C₆₀ (also known as buckyball or fullerene-C₆₀), tetracenes, xanthenes, perylenes, coumarins, rhodamines, quinacridones, dicyanomethylenepyrans, thiopyrans, polymethines, pyrylliums, fluoranthenes, periflanthrenes, silacyclopentadienes or siloles, thiapyrylliums, triazines, carbostyryls, metal and non-metal chelated bis(azinyl)amines, metal and non-metal chelated bis(azinyl)methenes.

The second organic compound of the invention can be selected from metal oxinoid compounds represented by Formula D: 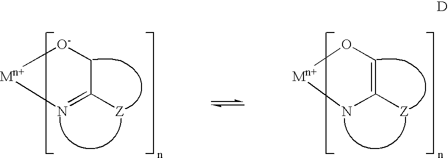
wherein

M represents a metal;

n is an integer of from 1 to 4; and

Z independently in each occurrence represents the atoms completing a nucleus having at least two fused aromatic rings.

The second organic compound can also be selected from compounds represented by Formula E:
(R^{S}-Q)₂-M-O-L E
wherein

M is a metal or non-metal;

Q in each occurrence represents a substituted 8-quinolinolato ligand;

R^{s} represents an 8-quinolinolato ring substituent chosen to block sterically the attachment of more than two substituted 8-quinolinolato ligands to the aluminum atom; and

L is a phenyl or aromatic fused ring moiety, which can be substituted with hydrocarbon groups such that L has from 6 to 24 carbon atoms.

The second organic compound(s) can be selected from compounds represented by Formulas D or E, with the provisos that at least one second organic compound is a low voltage electron-transporting material and that all second organic compounds have higher LUMO values than the first organic compound. Additional second organic compounds can be selected having Formulas D and E. Additional examples of second organic compounds represented by Formula E can be found in Bryan et al., U.S. Pat. No. 5,141,671, incorporated herein by reference.

Second organic compounds of the invention can be selected from phenanthroline or a derivative thereof as represented by Formula F: 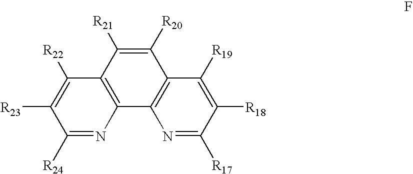
wherein

R₁₇, R₁₈, R₁₉, R₂₀, R₂₁, R₂₂, R₂₃ and R₂₄ are hydrogen or substituents; and

provided that any of the indicated substituents can join to form further fused rings.

Heterocyclic derivatives, represented by Formula G form a group of materials from which the second organic compounds of the invention can be selected: 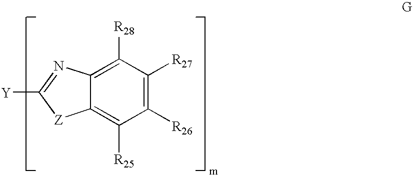
wherein

m is an integer of from 3 to 8;

Z is O, NR₂₉, or S;

R₂₅, R₂₆, R₂₇, R₂₈ and R₂₉ are hydrogen; alkyl of from 1 to 24 carbon atoms; aryl or hetero-atom substituted aryl of from 5 to 20 carbon atoms; or halo; or are the atoms necessary to complete a fused carbocyclic or heterocyclic ring; and

Y is a linkage unit usually comprising an alkyl or aryl group that conjugately or unconjugately connects the multiple benzazoles together.

Additional second organic compounds of the invention can be selected from silole or silacyclopentadiene derivatives represented by Formula H: 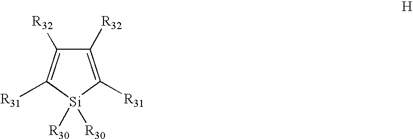
wherein

R₃₀, R₃₁, and R₃₂ are hydrogen or substituents or are the atoms necessary to complete a fused carbocyclic or heterocyclic ring.

Other second organic compounds of the invention can be selected from triazine derivatives represented by Formula I: 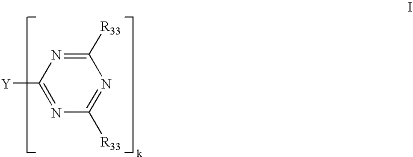
wherein

k is an integer of from 1 to 4;

R₃₃ is hydrogen, substituents or carbocyclic or heterocyclic rings; and

Y is a linkage unit usually comprising an alkyl or aryl group that conjugately or unconjugately connects the multiple triazines together.

Specific second organic compounds based on formulae D, E, F, G, H, and I are shown in the following structures:

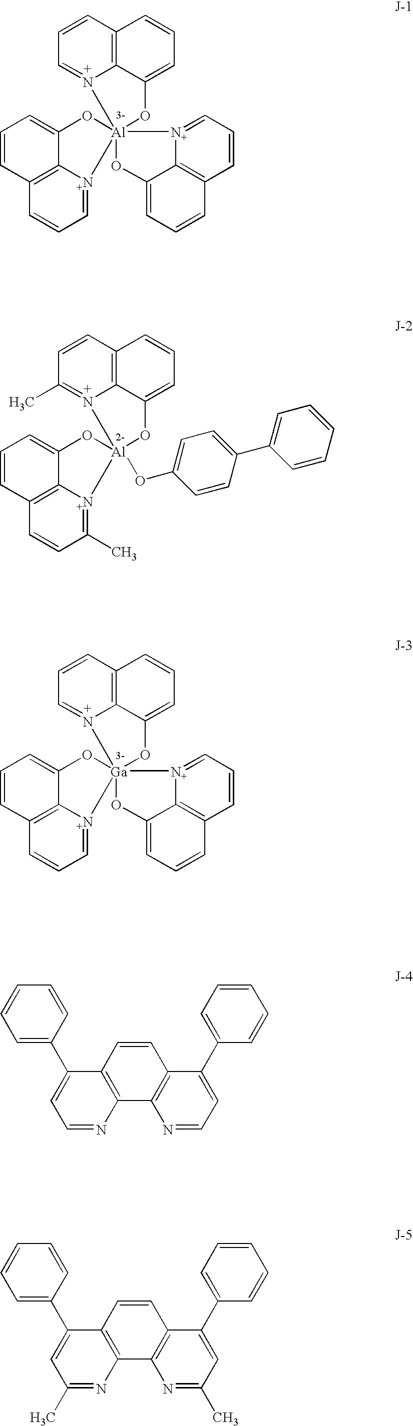

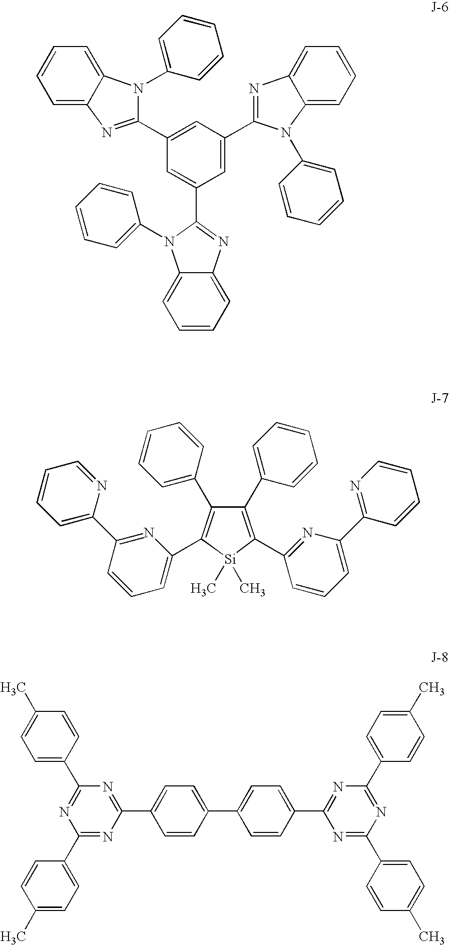

The amount of the first organic compound in the n-type doped organic layer is greater than or equal to 10% by volume of the layer but less than 100% by volume, and the total amount of the second organic compound(s) is less than or equal to 90% by volume of the layer but more than 0%. Particularly useful ranges for the first organic compound are 20, 40, 50, 60, 75 and 90%, with 80, 60, 50, 40, 25 and 10%, respectively, for the total amounts for the second organic compound(s) and the n-type dopant. Embodiments of the invention are those in which the amount of the first organic compound is selected from any value in the aforementioned range, the total amount of the second organic compound(s) is selected from any value in the aforementioned range and the amount of the n-type dopant is selected from the aforementioned range to fulfill the remainder, to 100%.

Preferred combinations of the invention are those wherein the first organic compounds are selected from C-7, C-8, C-9, and C-11, and the second organic compounds are selected from J-1, J-2, J-3, J-4, and J-5.

As described, the intermediate connector in the invention includes an n-type doped organic layer having an n-type dopant and an electron-transporting material comprising a first organic compound and at least one second compound as described herein. This combination in the intermediate connector in the aforementioned ratios gives devices that have reduced drive voltages even lower when compared to the devices in which either the first organic compound or second organic compound are incorporated alone in said connector.

Following are the chemical names and acronyms associated with compounds mentioned in the invention: C-1, rubrene, 5,6,11,12-tetraphenylnaphthacene; C-2, perylene; C-4, 9-(2-naphthyl)-10-(4-phenyl)phenylanthracene; C-5, ADN, 9,10-bis(2-naphthyl)-anthracene; C-6, tBADN, 2-tert-butyl-9,10-bis(2-naphthyl)-anthracene; C-7, tBDPN, 5,12-bis[4-tert-butylphenyl]naphthacene; C-10, TBP, 2,5,8,11-tetra-tert-butylperylene; J-1, Alq or Alq₃, tris(8-quinolinolato)aluminum (III); J-2, BAlq; B-3, Gaq or Gaq₃, tris(8-quinolinolato)gallium(III); J-4, BPhen, 4,7-diphenyl-1,10-phenanthroline; J-5, BCP, 2,9-dimethyl-4,7-diphenyl-1,10-phenanthroline; J-6, TPBI, 2,2′,2″-1,3,5-tris[1-phenyl-1H-benzimidazol-2-yl]benzene; and J-8, TRAZ, 4,4′-bis(4,6-di-(p-tolyl)-1,3,5-triazin-2-yl)-1,1′-biphenyl.

Electron-accepting layer 333 (if used) of intermediate connector 130.1 includes one or more organic materials, each having an electron-accepting property and a reduction potential greater than −0.5 V vs. a Saturated Calomel Electrode (SCE), and wherein the one or more organic materials constitute more than 50% by volume in intermediate connector 130.1. Such a layer can have both effective carrier injection and effective optical transparency in the tandem OLED. Preferably, electron-accepting layer 333 includes one or more organic materials having a reduction potential greater than −0.1 V vs. SCE. More preferably, electron-accepting layer 333 includes a single organic material having an electron-accepting property and a reduction potential greater than −0.1 V vs. SCE. By “electron-accepting property” it is meant that the organic material has the capability or tendency to accept at least some electronic charge from other nearby materials. The term “reduction potential”, expressed in volts, measures the affinity of a substance for an electron, the higher the positive number the greater the affinity. Reduction of hydronium ions into hydrogen gas would have a reduction potential of 0.00 V under standard conditions. The reduction potential of a substance can be conveniently obtained by cyclic voltammetry (CV) and it is measured vs. SCE. A useful method for the material herein has been described by Hatwar et al. in U.S. patent application Ser. No. 11/110,071, filed Apr. 20, 2005 by Hatwar et al., entitled “Tandem OLED Device”, the contents of which are incorporated by reference.

Organic materials suitable for use in electron-accepting layer 333 include simple compounds containing at least carbon and hydrogen, as well as metal complexes, e.g., transition metal complexes having organic ligands and organometallic compounds, as long as their reduction potentials are more positive than −0.5 V vs. SCE. Organic materials for electron-accepting layer 333 can include small molecules (capable of being deposited by vapor deposition), polymers, or dendrimers, or combinations thereof. It is also important that at least a portion of electron-accepting layer 333 does not significantly mix with adjacent layers. This can be accomplished by choosing materials having molecular weight high enough to prevent such diffusion. Preferably, the molecular weight of the electron-accepting material is greater than 350. To maintain the proper electron-accepting properties of the layer, it is desirable that the one or more organic materials constitute more than 90% by volume of the electron-accepting layer. For manufacturing simplicity, a single compound can be used for electron-accepting layer 333. Some examples of organic materials having a reduction potential greater than −0.5 V vs. SCE that can be used to form electron-accepting layer 333 include, but are not limited to, derivatives of hexaazatriphenylene and tetracyanoquinodimethane. A useful thickness of electron-accepting layer 333 is typically between 3 and 100 nm.

When used in the present invention, optional p-type doped organic layer 335 includes at least one organic host material and one p-type dopant, wherein the organic host material is capable of supporting hole transport. The hole-transporting materials used in conventional OLED devices, as described above, represent a useful class of host materials for p-type doped organic layer 335. Preferred materials include aromatic tertiary amines having at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Other suitable triarylamines substituted with one or more vinyl radicals or comprising at least one active hydrogen-containing group are disclosed by Brantley et al. in U.S. Pat. Nos. 3,567,450 and 3,658,520. A more preferred class of aromatic tertiary amines are those which include at least two aromatic tertiary amine moieties as described by VanSlyke et al. in U.S. Pat. Nos. 4,720,432 and 5,061,569. Nonlimiting examples include as N,N′-di(naphthalene-1-yl)-N,N′-diphenyl-benzidine (NPB) and N,N′-diphenyl-N,N′-bis(3-methylphenyl)-1,1-biphenyl-4,4′-diamine (TPD), and N,N,N′,N′-tetranaphthyl-benzidine (TNB).

Another preferred class of aromatic amines are dihydrophenazine compounds as described in commonly assigned U.S. patent application Ser. No. 10/390,973 filed Mar. 18, 2003 by Kevin P. Klubek et al., entitled “Cascaded Organic Electroluminescent Devices”, the disclosure of which is herein incorporated by reference. The combination of the aforementioned materials is also useful to form p-typed doped organic layer 335. More preferably, the organic host material in the p-type doped organic layer 335 includes NPB, TPD, TNB, 4,4′,4″-tris(N-3-metylphenyl-N-phenyl-amino)-triphenylamine (m-MTDATA), 4,4′,4″-tris(N,N-diphenyl-amino)-triphenylamine (TDATA), or dihydrophenazine compounds, or combinations thereof.

In some instances, the same host material can be used for both n-type and p-type doped organic layers, provided that it exhibits both hole- and electron-transporting properties set forth above. Examples of materials that can be used as host for either the n-type or p-type doped organic layers include, but are not limited to, various anthracene derivatives as described in U.S. Pat. No. 5,972,247, certain carbazole derivatives such as 4,4-bis(9-dicarbazolyl)-biphenyl (CBP), and distyrylarylene derivatives such as 4,4′-bis(2,2′-diphenyl vinyl)-1,1′-biphenyl, and as described in U.S. Pat. No. 5,121,029.

The p-type dopant in p-type doped organic layer 335 includes oxidizing agents with strong electron-withdrawing properties. “Strong electron-withdrawing properties” means that the organic dopant should be able to accept some electronic charge from the host to form a charge-transfer complex with the host material. Some nonlimiting examples include organic compounds such as 2,3,5,6-tetrafluoro-7,7,8,8-tetracyanoquinodimethane (F₄-TCNQ) and other derivatives of 7,7,8,8-tetracyanoquinodimethane (TCNQ), and inorganic oxidizing agents such as iodine, FeCl₃, FeF₃, SbCl₅, some other metal chlorides, and some other metal fluorides. A combination of p-type dopants is also useful to form p-type doped organic layer 335. The p-type dopant concentration is preferably in the range of 0.01-20 vol. %. The thickness of the p-type doped organic layer is typically less than 150 nm, and preferably in the range of about 1 to 100 nm.

A p-type doped organic layer can form at the interface of electron-accepting layer 333 and the HTL simply by deposition of the HTL material. In this invention, the materials chosen for the electron-accepting layer and the HTL are such that only a small amount of mixing occurs. That is, it is important that at least some of the electron-accepting layer does not mix with the HTL material.

When used in the present invention, optional interfacial layer 332 in intermediate connector 130.1 is mainly used to stop the possible interdiffusion between materials of n-typed doped organic layer 331 and electron-accepting layer 333, but can be used in other structures as will be seen. Interfacial layer 332 can be a metal compound or a metal. When used, the layer should be as thin as possible to be effective but reduce optical losses.

Interfacial layer 332 can include a metal compound selected from the stoichiometric or nonstoichiometric oxides, sulfides, selenides, tellurides, nitrides or carbides of titanium, zirconium, hafnium, niobium, tantalum, molybdenum, tungsten, manganese, iron, ruthenium, rhodium, iridium, nickel, palladium, platinum, copper, silicon, or germanium, stoichiometric or nonstoichiometric oxides, nitrides or carbides of zinc, stoichiometric or nonstoichiometric nitrides of gallium, stoichiometric or nonstoichiometric carbides of aluminum, or combinations thereof. Particularly useful metal compounds for use in interfacial layer 332 can be selected from MoO₃, NiMoO₄, CuMoO₄, WO₃, ZnTe, Al₄C₃, AlF₃, B₂S₃, CuS, GaP, InP, or SnTe. Preferably, the metal compound is selected from MoO₃, NiMoO₄, CuMoO₄, or WO₃. When using a metal compound, the thickness of interfacial layer 332 in intermediate connector 330 is in the range of from 0.5 nm to 20 nm.

Alternatively, interfacial layer 332 can include a high work function metal layer. The high work function metal used to form this layer has a work function no less than 4.0 eV and includes Ti, Zr, Ti, Nb, Ta, Cr, Mo, W, Re, Fe, Ru, Os, Co, Rh, Ir, Ni, Pd, Pt, Cu, Ag, Au, Zn, Al, In, or Sn, or combinations thereof. Preferably, the high work function metal layer includes Ag, Al, Cu, Au, Zn, In, or Sn, or combinations thereof. More preferably, the high work function metal includes Ag or Al. When using a high work function metal, the thickness of interfacial layer 332 in intermediate connector 130.1 is in the range of from 0.1 nm to 5 nm.

The electrons on the HOMO of the HTL of an electroluminescent unit can be readily injected onto the LUMO of an adjacent electron-accepting layer 333, and then injected onto the LUMO of n-type doped organic layer 331 adjacent to electron-accepting layer 333. n-Type doped organic layer 331 injects electrons into the ETL of the adjacent electroluminescent unit, and the electrons next move into the LEL (luminescent zone) where they recombine with holes to emit light, typically at an emissive dopant site in the LEL. Compared to the prior art intermediate connectors, the electrical potential drop (or voltage drop) across the intermediate connector can be reduced and the optical transparency can be increased. Since intermediate connector 130.1 comprises one or more organic layers, it can be readily formed at a relatively low temperature, preferably using a thermal evaporation method.

The overall thickness of intermediate connectors such as 130.1 is typically from 5 nm to 200 nm. If there are two or more intermediate connectors in a tandem OLED, the intermediate connectors can be the same or different from each other in terms of layer thickness, material selection, or both.

As mentioned previously, it is often useful to provide a hole-injecting layer (HIL) between the anode and the HTL. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. Nos. 6,127,004, 6,208,075, and 6,208,077, some aromatic amines, for example, m-MTDATA (4,4′,4″-tris[(3-methylphenyl)phenyl-amino]triphenylamine), and inorganic oxides including vanadium oxide (VOx), molybdenum oxide (MoOx), and nickel oxide (NiOx). Alternative hole-injecting materials reportedly useful in organic EL devices are described in EP 0 891 121 A1 and EP 1 029 909 A1. p-Type doped organic materials as described previously for use in the intermediate connector are also a useful class of hole-injecting materials. Hexaazatriphenylene derivatives are also useful HIL materials, as described in U.S. Pat. No. 6,720,573. A particularly useful HIL material is shown below

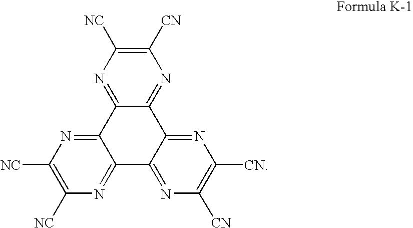

It is often useful to provide an electron-injecting layer (EIL) between the cathode and the ETL. n-Type doped organic layers as described previously for use in the intermediate connector are a useful class of electron-injecting materials.

The tandem OLED of the present invention is typically provided over a supporting substrate (not shown) where either the cathode or anode can be in contact with the substrate. The electrode in contact with the substrate is conveniently referred to as the bottom electrode. Conventionally, the bottom electrode is the anode, but the present invention is not limited to that configuration. The substrate can either be light transmissive or opaque, depending on the intended direction of light emission. The light transmissive property is desirable for viewing the EL emission through the substrate. Transparent glass or plastic is commonly employed in such cases. For applications where the EL emission is viewed through the top electrode, the transmissive characteristic of the bottom support is immaterial, and therefore can be light transmissive, light-absorbing, or light reflective. Substrates for use in this case include, but are not limited to, glass, plastic, semiconductor materials, silicon, ceramics, and circuit board materials. Of course, it is necessary to provide in these device configurations a light-transparent top electrode.

When EL emission is viewed through the anode 110, the anode should be transparent, or substantially transparent, to the emission of interest. Common transparent anode materials used in the present invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides such as gallium nitride, and metal selenides such as zinc selenide, and metal sulfides such as zinc sulfide, can be used as the anode. For applications where EL emission is viewed only through the cathode, the transmissive characteristics of the anode are immaterial and any conductive material can be used, regardless if it is transparent, opaque, or reflective. Example conductors for the present invention include, but are not limited to, gold, iridium, molybdenum, palladium, and platinum. Typical anode materials, transmissive or otherwise, have a work function no less than 4.0 eV. Desired anode materials are commonly deposited by any suitable way such as evaporation, sputtering, chemical vapor deposition, or electrochemical means. Anodes can be patterned using well-known photolithographic processes. Optionally, anodes can be polished prior to the deposition of other layers to reduce surface roughness so as to reduce electrical shorts or enhance reflectivity.

When light emission is viewed solely through anode 110, cathode 170 used in the present invention can be comprised of nearly any conductive material. Desirable materials have effective film-forming properties to ensure effective contact with the underlying organic layer, promote electron injection at low voltage, and have effective stability. Useful cathode materials often contain a low work function metal (<4.0 eV) or metal alloy. One preferred cathode material is comprised of an MgAg alloy wherein the percentage of silver is in the range of 1 to 20% by atomic ratio, as described in U.S. Pat. No. 4,885,211. Another suitable class of cathode materials includes bilayers comprising a thin inorganic EIL in contact with an organic layer (e.g., organic EIL, or organic ETL), which is capped with a thicker layer of a conductive metal. Here, the inorganic EIL preferably includes a low work function metal or metal salt and, if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861, 5,059,862, and 6,140,763.

When light emission is viewed through cathode 170, the cathode should be transparent or nearly transparent. For such applications, metals should be thin or one should use transparent conductive oxides, or include these materials. Optically transparent cathodes have been described in more detail in U.S. Pat. Nos. 4,885,211; 5,247,190; 5,703,436; 5,608,287; 5,837,391; 5,677,572; 5,776,622; 5,776,623; 5,714,838; 5,969,474; 5,739,545; 5,981,306; 6,137,223; 6,140,763; 6,172,459; 6,278,236; 6,284,393; and EP 1 076 368. Cathode materials are typically deposited by thermal evaporation, electron beam evaporation, ion sputtering, or chemical vapor deposition. When needed, patterning can be achieved through many well known methods including, but not limited to, through-mask deposition, integral shadow masking, for example, as described in U.S. Pat. No. 5,276,380 and EP 0 732 868, laser ablation, and selective chemical vapor deposition.

Referring back to FIG. 2, the important feature of this invention is that n-type doped organic layer 331 is adjacent to ETL 224.1 and includes an electron-transporting material that is different from the electron-transporting material used in the ETL. There are several reasons to select different electron-transporting materials for use in an ETL and an adjacent n-type doped organic layer.

First, the electron-transporting material of the ETL can be selected so that the diffusion of the n-type dopant is lower than it is in the electron-transporting material of the n-type doped organic layer. Through such selection, the diffusion of n-type dopants into the light-emitting layer can be reduced, thereby reducing unwanted excited-state quenching. For example, alkali metal dopants have relatively high diffusivity in phenanthroline-based electron-transporting materials. If both n-type doped organic layer 331 and ETL 224.1 include primarily phenanthroline derivatives, then the alkali metal dopants can readily diffuse from n-type doped organic layer 331 through ETL 224.1 and into the LEL 223.1. However, if the ETL 224.1 includes primarily metal oxinoid or triazine derivatives, the diffusion of alkali metal dopants is reduced. It is believed that electron-transporting materials having oxygen atoms are particularly effective at binding alkali metal cations and thereby reduce the diffusion of alkali metals.

Second, the electron-transporting material of the ETL can be selected so that it has a LUMO intermediate between the LEL and the electron-transporting material of n-type doped organic layer 331.

Third, the electron-transporting material of the ETL can be selected so as to alter the recombination zone in the LEL. Ordinarily, recombination occurs near the interface of the LEL and the HTL. In some cases, especially white emitting electroluminescent units, the HTL or a portion of the HTL is also doped with an emissive dopant and so the HTL can become a second light-emitting layer. By selecting an electron-transporting material in the ETL that readily promotes electron injection into the LEL (through high electron mobility or relative positioning of LUMO) the relative emission from the LEL or the doped HTL can be adjusted.

In a preferred embodiment, an electron-injecting layer is disposed between the cathode and the electron-transporting layer of an adjacent electroluminescent unit. In a particularly preferred embodiment, such electron-injecting layer includes an n-type dopant and an electron-transporting material that is different from the electron-transporting material used in the electron-transporting layer of the adjacent electroluminescent unit.

The organic materials mentioned above are suitably deposited through a vapor-phase method such as sublimation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by sublimation can be vaporized from a sublimation “boat” often comprised of a tantalum material, e.g., as described in U.S. Pat. No. 6,237,529, or can be first coated onto a donor sheet and then sublimed in closer proximity to the substrate. Layers with a mixture of materials can use separate sublimation boats or the materials can be premixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. Nos. 5,688,551; 5,851,709 and 6,066,357), and inkjet methods (U.S. Pat. No. 6,066,357).

Most OLED devices are sensitive to moisture or oxygen, or both, so they are commonly sealed in an inert atmosphere such as nitrogen or argon. In sealing an OLED device in an inert environment, a protective cover can be attached using an organic adhesive, a metal solder, or a low-melting-temperature glass. Commonly, a getter or desiccant is also provided within the sealed space. Useful getters and desiccants include alkali and alkaline metals, alumina, bauxite, calcium sulfate, clays, silica gel, zeolites, alkaline metal oxides, alkaline earth metal oxides, sulfates, metal halides, and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

OLED devices of the present invention can employ various well-known optical effects in order to enhance their properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters in functional relationship with the light-emitting areas of the display. Filters, polarizers, and anti-glare or anti-reflection coatings can also be provided over a cover or as part of a cover.

White or broadband emission can be combined with color filters to provide full color or multicolor display. The color filters can include red, green, and blue filters. There can also be provided a color system that includes color filters to provide red, green, blue and white pixels, e.g., as described in US Patent Application Publication 2004/0113875 A1. In place of white, yellow or cyan can be used. Five or more color systems can also be useful.

The OLED device can have a microcavity structure. In one useful example, one of the metallic electrodes is essentially opaque and reflective; the other one is reflective and semitransparent. The reflective electrode is preferably selected from Au, Ag, Mg, Ca, or alloys thereof. Because of the presence of the two reflecting metal electrodes, the device has a microcavity structure. The strong optical interference in this structure results in a resonance condition, wherein emission near the resonance wavelength is enhanced and emission away from the resonance wavelength is depressed. The optical path length can be tuned by selecting the thickness of the organic layers or by placing a transparent optical spacer between the electrodes. For example, an OLED device of this invention can have ITO spacer layer placed between a reflective anode and the organic electroluminescent media, with a semitransparent cathode over the organic electroluminescent media.

The present invention can be employed in most OLED device applications. These include very simple structures comprising a single anode and cathode to more complex devices, such as area color displays, passive matrix displays comprised of orthogonal arrays of anodes and cathodes to form pixels, and active matrix displays where each pixel is controlled independently, for example, with thin film transistors (TFTs). The invention can also be employed for devices where the OLED is used as a light source, for example, in solid-state lighting or backlights for LCD displays.

The electroluminescent device of the invention is useful in any device where stable light emission is desired, e.g. a lamp or a component in a static or motion imaging device, such as a television, cell phone, DVD player, or computer monitor. Typical embodiments of the invention provide not only improved drive voltage but can also provide improved luminance efficiency, operational stability and low voltage rise.

### EXAMPLES

The invention and its advantages can be better appreciated by the following inventive and comparative examples.

### Example 1 (Comparative)

A comparative OLED device was constructed in the following manner:
1. A clean glass substrate was vacuum-deposited with indium tin oxide (ITO) to form a transparent electrode of 20 nm thickness;
2. The above-prepared ITO surface was treated with a plasma oxygen etch, followed first by plasma deposition of a 0.5 nm layer of a fluorocarbon polymer (CFx) as described in U.S. Pat. No. 6,208,075, and then by deposition of a 10 nm layer of hexacyanohexaazatriphenylene (Compound K-1);
3. The above-prepared substrate was further treated by vacuum-depositing a 20 nm layer of 4,4′-bis[N-(1-naphthyl)-N-phenylamino]biphenyl (NPB) as a hole-transporting layer (HTL);
4. A 20 nm layer of NPB (as host) with 20% 9-(2-naphthyl)-10-(biphenyl-4-yl)anthracene (Compound AH3, above) and 2.5% 5,1-bis(biphenyl-4-yl)-6,12-bis(4-tert-butylphenyl)-3,9-di-tert-butylnaphthacene (Compound C-8, above) was vacuum-deposited onto the substrate at a coating station that included a heated graphite boat source to form a yellow-light-emitting layer (yellow LEL);
5. A coating of 20 nm of Compound AH3 as host with 6% NPB and 1.5% 2,5,8,11-tetra-tert-butylperylene (TBP, C-10) was evaporatively deposited on the above substrate to form a blue light-emitting layer (blue LEL);
6. A 2.5 nm layer of tris(8-quinolinolato)aluminum (III) (ALQ) was vacuum-deposited onto the substrate at a coating station that included a heated graphite boat source to form a buffer layer;
7. A 20 nm layer of tris(8-quinolinolato)aluminum (III) (ALQ) doped with 2% lithium metal was vacuum-deposited onto the substrate at a coating station that included a heated graphite boat source to form an n-type doped organic layer of an intermediate connector;
8. A 12 nm layer of Compound K-1 was deposited as an electron-accepting layer of an intermediate connector;
9. The above-prepared substrate was further treated by vacuum-depositing a 75 nm layer of 4,4′-bis[N-(1-naphthyl)-N-phenylamino]biphenyl (NPB) as a hole-transporting layer (HTL);
10. A 20 nm layer of NPB (as host) with 20% 9-(2-naphthyl)-10-(biphenyl-4-yl)anthracene (Compound AH3, above) and 2.5% 5,11-bis(biphenyl-4-yl)-6,12-bis(4-tert-butylphenyl)-3,9-di-tert-butylnaphthacene (Compound C-8, above) was vacuum-deposited onto the substrate at a coating station that included a heated graphite boat source to form a yellow-light-emitting layer (yellow LEL);
11. A coating of 20 nm of Compound AH3 as host with 6% NPB and 1.5% 2,5,8,11-tetra-tert-butylperylene (TBP, C-10) was evaporatively deposited on the above substrate to form a blue light-emitting layer (blue LEL);
12. A 2.5 nm layer of tris(8-quinolinolato)aluminum (III) (ALQ) was vacuum-deposited onto the substrate at a coating station that included a heated graphite boat source to form a buffer layer;
13. A 20 nm layer of tris(8-quinolinolato)aluminum (III) (ALQ) doped with 2% lithium metal was vacuum-deposited onto the substrate at a coating station that included a heated graphite boat source to form an electron-transporting layer;
14. A 0.5 nm layer of LiF was deposited as an electron-injecting layer; and
15. A 100 nm aluminum cathode layer was deposited onto the electron-transporting layer at a coating station with a tantalum boat.
16. The device was then transferred to a dry box for encapsulation.

### Example 2 (Inventive)

An inventive OLED device was constructed as in Example 1, except that in steps 7 and 13 the layer was a 50:50 mixture of Alq and Compound C-8 doped with 2% lithium metal.

### Results (Examples 1-2)

The devices were tested by applying a current across the electrodes of 20 mA/cm² and measuring the spectrum and required drive voltage. The relative luminous efficiency is defined as the luminous efficiency of the example device, in cd/A, divided by the luminous efficiency in, cd/A, of reference Example 1. The CIE change magnitude is the magnitude of the color change in CIE color space relative to reference Example 1. The following table shows the results.

TABLE 1

Example

| | 1 | 2 |
|---|---|---|
| Type (Inventive or Comparative) | Comp | Inv |
| Drive voltage at 20 mA/cm² | 11.7 | 10.5 |
| Relative Drive voltage | 1.00 | 0.90 |
| Yield (cd/A) | 17.3 | 17 |
| Relative Luminous Efficiency | 1.00 | 0.98 |
| CIE x | 0.31 | 0.32 |
| CIE y | 0.33 | 0.34 |
| CIE change magnitude | — | 0.01 |

LUMO Values.

An important relationship exists when selecting the first compound(s) and second compound(s) of the invention. A comparison of the LUMO values of the first and second compounds in the layer of the invention, must be carefully considered. In devices of the invention, for there to be a drive voltage reduction over devices that contain only a first compound or only a second compound, there must be a difference in the LUMO values of the compounds. The first compound must have a lower LUMO value (more negative) than the second compound, or compounds (less negative).

The LUMO values are typically determined experimentally by electrochemical methods. A Model CHI660 electrochemical analyzer (CH Instruments, Inc., Austin, Tex.) was employed to carry out the electrochemical measurements. Cyclic voltammetry (CV) and Osteryoung square-wave voltammetry (SWV) were used to characterize the redox properties of the compounds of interest. A glassy carbon (GC) disk electrode (A=0.071 cm²) was used as working electrode. The GC electrode was polished with 0.05 um alumina slurry, followed by sonication cleaning in Milli-Q deionized water twice and rinsed with acetone in between water cleaning. The electrode was finally cleaned and activated by electrochemical treatment prior to use. A platinum wire served as counter electrode and a saturated calomel electrode (SCE) was used as a quasi-reference electrode to complete a standard 3-electrode electrochemical cell. Ferrocene (Fc) was used as an internal standard (E_{Fc}=0.50 V vs. SCE in 1:1 acetonitrile/toluene, 0.1 M TBAF). Mixture of acetonitrile and toluene (50%/50% v/v, or 1:1) was used as organic solvent system. The supporting electrolyte, tetrabutylammonium tetraflouroborate (TBAF) was recrystallized twice in isopropanol and dried under vacuum. All solvents used were low water grade (<20 ppm water). The testing solution was purged with high purity nitrogen gas for approximately 5 minutes to remove oxygen and a nitrogen blanket was kept on the top of the solution during the course of the experiments. All measurements were performed at ambient temperature of 25±1° C. The oxidation and reduction potentials were determined either by averaging the anodic peak potential (Ep,a) and cathodic peak potential (Ep,c) for reversible or quasi-reversible electrode processes or on the basis of peak potentials (in SWV) for irreversible processes. All LUMO values pertaining to this application are calculated from the following:

Formal reduction potentials vs. SCE for reversible or quasi-reversible processes;
E^{o}′_{red}=(Eₚₐ+E_{pc})/2
Formal reduction potentials vs. Fc;
E^{o}′_{red}vs.Fc=(E^{o}′_{red}vs.SCE)−E_{Fc}
where E_{Fc} is the oxidation potential Eₒₓ, of ferrocene;
Estimated lower limit for LUMO;
LUMO=HOMO_{Fc}−(E^{o}′_{red}vs.Fc)
where HOMO_{Fc} (Highest Occupied Molecular Orbital for ferrocene)=−4.8 eV.

The LUMO values for some first and second compounds are listed in Table 2. To make a selection of compounds useful in the invention, the first compound should have a lower LUMO value than its paired second compound(s).

TABLE 2

| Material | LUMO (eV) |
|---|---|
| ALQ (J-1) | −2.50 |
| Compound C-8 | −2.72 |
| Bphen (J-4) | −2.4 |

Device Fabrication For Low Voltage Electron Transport Determination
EL devices to determine if a material qualifies as a low voltage electron transport material were constructed in the following manner:

A glass substrate coated with an 85 nm layer of indium-tin oxide (ITO) as the anode was sequentially ultrasonicated in a commercial detergent, rinsed in deionized water, degreased in toluene vapor and exposed to oxygen plasma for about 1 min.

a) Over the ITO was deposited a 1 nm fluorocarbon (CFₓ) hole-injecting layer (HIL) by plasma-assisted deposition of CHF₃.

b) A hole-transporting layer (HTL) of N,N′-di-1-naphthalenyl-N,N′-diphenyl-4,4′-diaminobiphenyl (NPB) having a thickness of 75 nm was then evaporated onto a).

c) A 35 nm light-emitting layer (LEL) of tris(8-quinolinolato)aluminum (III) (Alq) was then deposited onto the hole-transporting layer.

d) A 35 nm layer of the material to be tested for low voltage electron transport properties as exemplified in Table 3 were then deposited onto the light-emitting layer.

e) On top of the ETL was deposited a 0.5 nm layer of LiF.

f) On top of the LiF layer was deposited a 130 nm layer of Al to form the cathode.

The above sequence completed the deposition of the EL device. The device was then hermetically packaged in a dry glove box for protection

The further layer as described in the invention contains a first compound and a second compound. The second compound is a low voltage electron-transporting compound. The combination of both the first and second compounds in the further layer of the invention in the aforementioned ratios, give devices that have reduced drive voltages that are even lower when compared to the devices in which either the first or second compound are incorporated alone in said layer.

Low voltage electron transport materials are materials that when incorporated alone into the electron transporting layer, as described in paragraph d) of the current device result in drive voltages of 13 volts or less. Low voltage electron transport materials with drive voltages of 10 volts or less are also useful as second compounds of the invention while materials of 8 volts or less are preferred as second compounds. Materials tested for low drive voltages and the results are shown in Table 3.

TABLE 3
Low Voltage Electron Transport Materials

| Sample | Material | Type | Drive Voltage (volts) |
|---|---|---|---|
| 1 | J-1 | Low | 8.0 |
| 2 | J-5 | Low | 9.9 |
| 3 | J-6 | Low | 8.3 |
| 4 | C-4 | High | 13.7 |
| 5 | C-7 | High | 15.4 |
| 6 | C-10 | High | 16.5 |
| 7 | CBP | High | 14.3 |

Table 3 shows that compounds J-1, J-5 and J-6 qualify as low voltage electron transport materials while C-4, C-7, C-10 and CBP do not.

As can be seen in Table 1, when the low-voltage electron-transporting material is used in conjunction with a polycyclic aromatic hydrocarbon compound (Compound C-8) with the lowest LUMO value of the compounds in the layer and with the metal lithium (Example 2), the results show a reduced drive voltage with a high luminous efficiency and a negligible color shift. This shows that the combination of a polycyclic aromatic hydrocarbon compound that has the lowest LUMO value of the compounds in the layer, a second compound exhibiting a higher LUMO value that is also a low voltage electron-transporting material, and a metallic material based on a metal having a work function less than 4.2 eV as described herein in this invention provides the advantages of operating the OLED device at a lower voltage without a color shift that is sometimes seen with other materials that provide a lower operating voltage.

The invention has been described in detail with particular reference to certain preferred embodiments thereof, but it will be understood that variations and modifications can be effected within the spirit and scope of the invention.

### Parts List

100 tandem OLED device
110 anode
120.1 first electroluminescent unit
120.2 second electroluminescent unit
120.(N−1) (N−1)^{th} electroluminescent unit
120.N N^{th} electroluminescent unit
130.1 first intermediate connector
130.2 second intermediate connector
130.(N−1) (N−1)^{th} intermediate connector cathode
170 voltage/current source
190 electrical conductors
200 tandem OLED device
221.1 HIL of the 1^{st} electroluminescent unit
222.1 HTL of the 1^{st} electroluminescent unit
222.2 HTL of the 2^{nd} electroluminescent unit
223.1 LEL of the 1^{st} electroluminescent unit
223.2 LEL of the 2^{nd} electroluminescent unit
224.1 ETL of the 1^{st} electroluminescent unit
224.2 ETL of the 2^{nd} electroluminescent unit
226.2 EIL of the 2^{nd} electroluminescent unit
331 n-type doped organic layer
332 interfacial layer
333 electron-accepting layer
335 p-type doped organic layer

1. A tandem OLED device, comprising:
a) an anode;
b) a cathode;
c) at least first and second electroluminescent units disposed between the anode and the cathode, wherein each of the electroluminescent units includes at least one individually selected organic light-emitting layer; and
d) an intermediate connector disposed between the first and second electroluminescent units, wherein the intermediate connector includes an n-type doped organic layer having an n-type dopant and an electron-transporting material, wherein such electron-transporting material is a mixture of:
i) a first organic compound that has the lowest LUMO value of the compounds in the n-type doped organic layer, in an amount greater than or equal to 10% by volume and less than 100% by volume of the layer; and
ii) at least one second organic compound exhibiting a higher LUMO value than the first organic compound, where at least one of the second organic compounds is a low voltage electron-transporting material, and the total amount of such second organic compounds(s) is less than or equal to 90% by volume of the layer.

2. The OLED device of claim 1 wherein the n-type dopant is a
metallic material.

3. The OLED device of claim 2 wherein the metallic material is Cs or Li.

4. The OLED device of claim 1 wherein the second organic compound is phenanthroline or a derivative thereof.

5. The OLED device of claim 1 wherein the second organic compound is a metal oxinoid.

6. The OLED device of claim 1 wherein the first organic compound is a polycyclic aromatic hydrocarbon compound.

7. The OLED device of claim 6 wherein the polycyclic aromatic hydrocarbon compound is represented by Formula A: 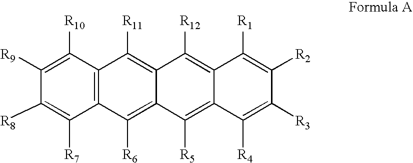
wherein:
R₁, R₂, R₃, R₄, R₅, R₆, R₇, R₈, R₉, R₁₀, R₁₁, and R₁₂ are independently selected as hydrogen or substituents;
provided that any of the indicated substituents can join to form further fused rings.

8. The OLED device of claim 7 wherein at least one of R₁, R₂, R₃, R₄, R₅, R₆, R₇, R₈, R₉, R₁₀, R₁₁, and R₁₂ are independently selected from alkyl and aryl groups.

9. The OLED device of claim 7 wherein the polycyclic aromatic hydrocarbon compound is rubrene or a derivative thereof.

10. The OLED device of claim 9 wherein the second compound is phenanthroline or a derivative thereof.

11. The OLED device of claim 10 wherein the second compound is a metal oxinoid.

12. The OLED device of claim 7 wherein the n-type dopant is a metallic material.

13. The OLED device of claim 12 wherein the metallic material is Cs or Li.

14. The tandem OLED device of claim 1 wherein the light emitted by at least one of the electroluminescent units is white.

15. The tandem OLED device of claim 14 wherein each of the white-emitting electroluminescent units has two or more light-emitting layers that combine to produce white light.

16. The tandem OLED device of claim 1 wherein the intermediate connector further includes a p-type doped organic layer, the p-type doped organic layer being disposed closer than the n-type doped organic layer to the cathode.

17. The tandem OLED device of claim 16 wherein the intermediate connector further includes an interfacial layer disposed between the n-type doped organic layer and the p-type doped organic layer, such interfacial layer including a metal or metal compound.

18. The tandem OLED device of claim 1 wherein the intermediate connector further includes an electron-accepting layer disposed closer than the n-type doped organic layer to the cathode, and wherein the electron-accepting layer includes one or more organic materials, each having a reduction potential greater than −0.5 V vs. a Saturated Calomel Electrode, and wherein the one or more organic materials constitutes more than 50% by volume of the electron-accepting layer.

19. The tandem OLED device of claim 18 wherein the intermediate connector further includes a p-type doped organic layer in contact with the electron-accepting layer, the p-type doped organic layer being disposed closer than the electron-accepting layer to the cathode.

20. The tandem OLED device of claim 19 wherein the intermediate connector further includes an interfacial layer disposed between the n-type doped organic layer and the electron-accepting layer, such interfacial layer including a metal or metal compound.
